(19) United States
(12) Patent Application Publication
(10) Pub. No.: US 2021/0202288 A1
(43) Pub. Date: Jul. 1, 2021

(54) DEVICE AND METHOD FOR MANUFACTURING THIN FILM

(71) Applicants: BOE TECHNOLOGY GROUP CO., LTD., Beijing (CN); CHENGDU BOE OPTOELECTRONICS TECHNOLOGY CO., LTD., Chengdu, Sichuan (CN)

(72) Inventors: Quanqin SUN, Beijing (CN); Xiaodong YANG, Beijing (CN); Ang XIAO, Beijing (CN); Guowei LI, Beijing (CN); Hongjian WU, Beijing (CN); Yangyang ZHANG, Beijing (CN)

(73) Assignees: BOE TECHNOLOGY GROUP CO., LTD., Beijing (CN); CHENGDU BOE OPTOELECTRONICS TECHNOLOGY CO., LTD., Chengdu, Sichuan (CN)

(21) Appl. No.: 16/079,133

(22) PCT Filed: Dec. 14, 2017
(86) PCT No.: PCT/CN2017/116106

§ 371 Date: Aug. 23, 2018

(30) Foreign Application Priority Data
May 15, 2017 (CN) 201710337765.8

(51) Int. Cl. H01L 21/68; H01L 51/56; H01L 51/52; C23C 14/04; C23C 14/50; C23C 14/24; C23C 16/04; C23C 16/458; C23C 14/54; C23C 16/52

(52) U.S. Cl. CPC H01L 21/682; H01L 51/56; H01L 51/5253; C23C 14/042; C23C 16/52; C23C 14/24; C23C 16/042; C23C 16/4583; C23C 14/542; C23C 14/50

(57) ABSTRACT

A device and a method for manufacturing a thin film are provided. The device includes: a chamber; a substrate carrying member arranged within the chamber and configured to carry thereon a substrate on which the thin film is to be formed; a mask fixation member configured to fix a mask, wherein the mask includes a shielding region and an opening region, and a material for forming the thin film is allowed to pass through the opening region; and a position adjustment member configured to adjust a distance between the mask and the substrate to form the thin films of different sizes on the substrate, wherein orthogonal projections of the thin films of different sizes onto the substrate have different areas.

### CROSS-REFERENCE TO RELATED APPLICATION

The present application claims priority to the Chinese patent application No. 201710337765.8 filed on May 15, 2017, which is hereby incorporated by reference in its entirety.

### TECHNICAL FIELD

The present disclosure relates to the manufacture of thin film, in particular to a device and a method for manufacturing a thin film.

### BACKGROUND

Usually, an organic light-emitting diode (OLED) substrate is encapsulated through a thin film encapsulation (TFE) process. A thin film encapsulation layer for encapsulating the OLED substrate includes typically three encapsulation layers, i.e., a first inorganic layer, an organic layer and a second inorganic layer formed sequentially.

Currently, for a TFE method, the three encapsulation layers need to be sequentially deposited in different chambers or devices, and each chamber or device is used for the formation (e.g., deposition) of one encapsulation layer. In addition, respective masks need to be designed for different encapsulation layers, and these masks have opening regions of different sizes.

The above TPE method has the following disadvantages. 1) At least three chambers or devices for different processes need to be provided, resulting in an increase in the equipment cost. 2) The to-be-encapsulated OLED substrate needs to be delivered among the different devices, resulting in an increased possibility of a product being adversely affected by particles. 3) Prior to the deposition of each encapsulation layer, it is necessary to perform an alignment process on the encapsulation layer, resulting in an increase in the alignment difficulty. 4) It is necessary to provide various mask designs for each product, resulting in an increase in the design cost and the management difficulty.

### SUMMARY

An object of the present disclosure is to provide a device and a method for manufacturing a thin film, so as to solve the above-mentioned problems.

In one aspect, the present disclosure provides in some embodiments a device for manufacturing a thin film, including: a chamber; a substrate carrying member arranged within the chamber and configured to carry thereon a substrate on which the thin film is to be formed; a mask fixation member configured to fix a mask, wherein the mask includes a shielding region and an opening region, and a material for forming the thin film is allowed to pass through the opening region; and a position adjustment member configured to adjust a distance between the mask and the substrate to form the thin films of different sizes on the substrate, wherein orthogonal projections of the thin films of different sizes onto the substrate have different areas.

In a possible embodiment of the present disclosure, the substrate carrying member is further configured to carry thereon an organic light-emitting diode (OLED) substrate on which a thin film encapsulation layer is to be formed, and the OLED substrate includes a base substrate and an OLED device arranged on the base substrate. The position adjustment member is further configured to adjust a distance between the mask and the substrate, to form at least two thin film encapsulation layers of different sizes on the OLED substrate.

In a possible embodiment of the present disclosure, the at least two thin film encapsulation layers include at least a first inorganic layer and an organic layer, and a size of the first inorganic layer is greater than a size of the organic layer. The position adjustment member is further configured to adjust the distance between the mask and the substrate to be a first distance prior to the formation of the first inorganic layer, and adjust the distance between the mask and the substrate to a second distance prior to the formation of the organic layer, wherein the second distance is smaller than the first distance.

In a possible embodiment of the present disclosure, the at least two thin film encapsulation layers further include a second inorganic layer, and a size of the second inorganic layer is greater than the size of the first inorganic layer. The position adjustment member is further configured to adjust the distance between the mask and the substrate to be a third distance prior to the formation of the second inorganic layer, wherein the third distance is greater than the first distance.

In a possible embodiment of the present disclosure, the OLED substrate on which the thin film encapsulation layer is to be formed further includes a first inorganic layer covering the OLED device, and the at least two thin film encapsulation layers include an organic layer and a second inorganic layer. The position adjustment member is further configured to adjust the distance between the mask and the substrate to be a second distance prior to the formation of the organic layer, and adjust the distance between the mask and the substrate to be a third distance prior to the formation of the second inorganic layer, wherein the third distance is greater than the second distance.

In a possible embodiment of the present disclosure, the substrate carrying member includes a lifting table, and the position adjustment member is further configured to control the lifting table to move upward or downward, to adjust the distance between the mask and the substrate; and/or the mask fixation member is liftable, and the position adjustment member is further configured to control the mask fixation member to move upward or downward, to adjust the distance between the mask and the substrate.

In a possible embodiment of the present disclosure, the device further includes an alignment member configured to align the mask with the substrate, to enable the opening region of the mask to directly face a region of the substrate where the thin film is to be formed.

In a possible embodiment of the present disclosure, the device further includes a gas supply member configured to supply a corresponding process gas into the chamber in accordance with a type of the thin film to be formed.

In a possible embodiment of the present disclosure, the gas supply member is further configured to set an amount and a supply time period of the process gas in accordance with a size and a thickness of the thin film to be formed.

In a possible embodiment of the present disclosure, the gas supply member is arranged at a side of the mask distal to the substrate.

In another aspect, the present disclosure provides in some embodiments a method for manufacturing a thin film, including: placing a substrate onto a substrate carrying member within a chamber, wherein a thin film is to be formed on the substrate; fixing a mask onto one side of the substrate, wherein the mask includes a shielding region and an opening region, and a material for forming the thin film is allowed to pass through the opening region; and adjusting a distance between the mask and the substrate to form the thin films of different sizes on the substrate, wherein orthogonal projections of the thin films of different sizes onto the substrate have different areas.

In a possible embodiment of the present disclosure, prior to the step of adjusting the distance between the mask and the substrate, the method further includes: aligning the mask with the substrate, to enable the opening region of the mask to directly face a region of the substrate where the thin film is to be formed.

In a possible embodiment of the present disclosure, the step of placing the substrate onto the substrate carrying member within the chamber includes: placing an OLED substrate onto the substrate carrying member, wherein a thin film encapsulation layer is to be formed on the OLED substrate, and the OLED substrate includes a base substrate and an OLED device arranged on the base substrate. The step of adjusting the distance between the mask and the substrate to form the thin films of different sizes on the substrate includes: adjusting the distance between the mask and the substrate, to form at least two thin film encapsulation layers of different sizes on the OLED substrate.

In a possible embodiment of the present disclosure, the at least two thin film encapsulation layers include at least a first inorganic layer and an organic layer. The step of adjusting the distance between the mask and the substrate, to form the at least two thin film encapsulation layers of different sizes on the OLED substrate includes: adjusting the distance between the mask and the substrate to be a first distance, and forming the first inorganic layer on the substrate; and adjusting the distance between the mask and the substrate to be a second distance, and forming the organic layer on the substrate, wherein the second distance is smaller than the first distance, and a size of the first inorganic layer is greater than a size of the organic layer.

In a possible embodiment of the present disclosure, the at least two thin film encapsulation layers further include a second inorganic layer. Subsequent to the step of adjusting the distance between the mask and the substrate to be a second distance, and forming the organic layer on the substrate, the method further includes: adjusting the distance between the mask and the substrate to be a third distance, and forming the second inorganic layer on the substrate, wherein the third distance is greater than the first distance, and a size of the second inorganic layer is greater than the size of the first inorganic layer.

In a possible embodiment of the present disclosure, the method further includes: supplying a first process gas into the chamber in the case of forming the first inorganic layer and the second inorganic layer, and supplying a second process gas into the chamber in the case of forming the organic layer, wherein the second process gas is different from the first process gas.

In a possible embodiment of the present disclosure, the step of adjusting the distance between the mask and the substrate includes: adjusting the distance between the mask and the substrate by controlling the substrate and/or the mask to move upward or downward.

According to the device for manufacturing the thin film provided by the embodiments of the present disclosure, the thin films of different sizes are formed through the same mask, so it is able to reduce the equipment cost. In the case of forming a plurality of layers of thin films, it is unnecessary to deliver the substrate among different devices, so it is able to reduce the possibility of the product being adversely affected by particles. In addition, it is unnecessary to design the mask for each layer of thin film, so it is able to reduce the design cost and the management difficulty.

### BRIEF DESCRIPTION OF THE DRAWINGS

FIG. 1 is a schematic view showing an OLED panel;

FIG. 2 is a schematic view showing a mask shadow effect in the case that a thin film is formed on a substrate with a mask;

FIG. 3 is a curve diagram of a correspondence between a distance between the mask and the substrate and a distance between the thin film deposited under a shielding region of the mask and an edge of an opening region of the mask acquired through a thin film deposition experiment;

FIG. 4 is a flow chart of a method for manufacturing a thin film according to one embodiment of the present disclosure; and

FIGS. 5-11 are schematic views showing the deposition of thin film encapsulation layers onto an OLED substrate according to one embodiment of the present disclosure.

### DETAILED DESCRIPTION OF THE EMBODIMENTS

FIG. 1 is a schematic view showing an OLED panel. As shown in FIG. 1, the OLED panel includes an OLED substrate and thin film encapsulation layers for encapsulating the OLED substrate. The OLED substrate includes a base substrate 101 and an OLED device 102 arranged on the base substrate 101. The thin film encapsulation layers include three layers of encapsulation thin film, i.e., a first inorganic layer 103, an organic layer 104 and a second inorganic layer 105. The first inorganic layer 103 has a size slightly greater than a size of the organic layer 104, and the second inorganic layer 105 has a size slightly greater than a size of the first inorganic layer 103.

A device and a method for manufacturing a thin film in the embodiments of the present disclosure may be applied to an evaporation or deposition process, e.g., a TFE process for the OLED substrate in FIG. 1.

At first, a principle in the embodiments of the present disclosure will be described hereinafter.

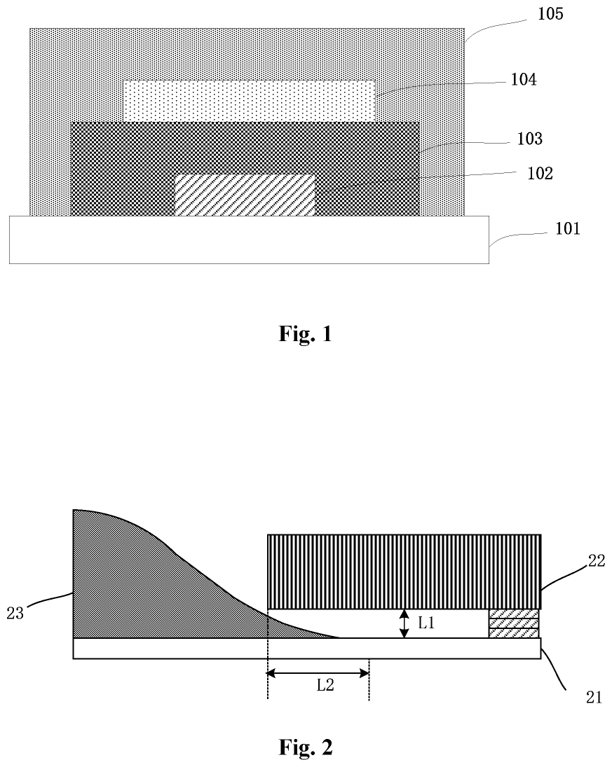

As shown in FIG. 2 which is a schematic view showing a mask shadow effect in the case that a thin film is formed on a substrate with a mask, the mask 22 has a shielding region and an opening region, and a pattern of the opening region corresponds a pattern of the thin film 23 formed (e.g., deposited) on the substrate 21. During the deposition, there is a certain distance L1 between the mask 22 and the substrate 21, so the mask shadow effect may occur, i.e., the resultant pattern of the thin film 23 does not completely conform to the pattern of the opening region. At this time, a part of the thin film may be deposited at a position under the shielding region of the mask 22. As shown in FIG. 2, a part of the thin film, a distance between which and an edge of the opening region is L2, may be formed at a position under the shielding region of the mask 22.

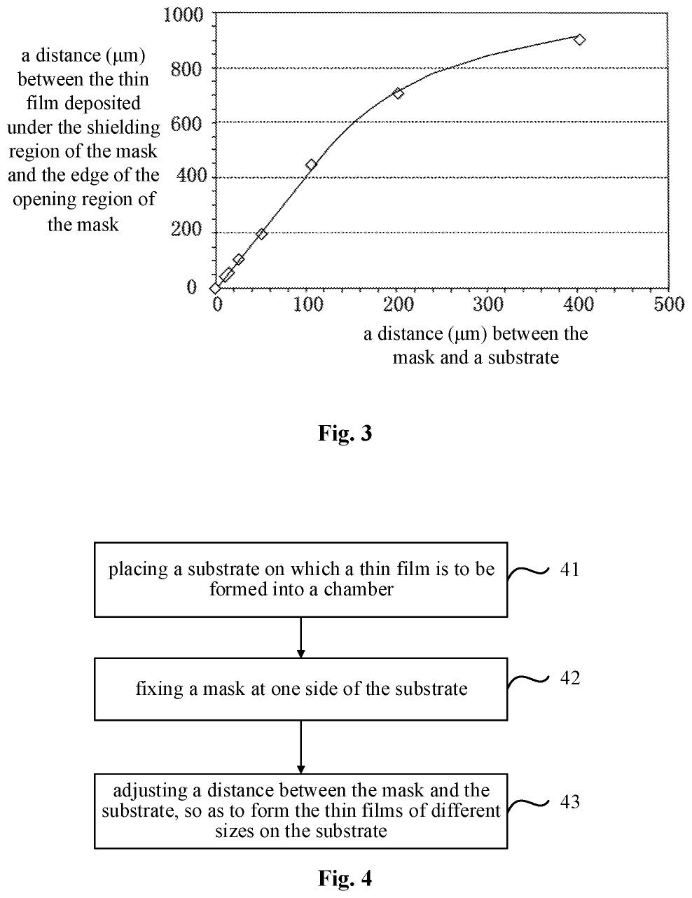

As shown in FIG. 3 which is a curve diagram of a correspondence between a distance between the mask and the substrate and a distance between the thin film deposited under the shielding region of the mask and the edge of the opening region of the mask acquired by measurement through a thin film deposition experiment, the larger the distance between the mask and the substrate, the larger the size of the part of the thin film deposited at the position under the shielding region of the mask, i.e., the larger the distance between the part of the thin film deposited at the position under the shielding region of the mask and the edge of the opening region. In contrast, the smaller the distance between the mask and the substrate, the smaller the size of the part of the thin film deposited at the position under the shielding region of the mask.

In the embodiments of the present disclosure, based on the above principle, through adjusting the distance between the mask and the substrate, it is able to form the thin films of different sizes using a same thin film manufacturing device and a same mask.

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

The present disclosure provides in some embodiments a device for manufacturing a thin film, which includes: a chamber (e.g., a thin film deposition chamber); a substrate carrying member arranged within the chamber and configured to carry thereon a substrate on which the thin film is to be formed; a mask fixation member configured to fix a mask, the mask including a shielding region and an opening region through which a material for forming the thin film is allowed to pass; and a position adjustment member configured to adjust a distance between the mask and the substrate according to the size of the thin film to be formed, so as to form the thin films of different sizes on the substrate, orthogonal projections of the thin films of different sizes onto the substrate having different areas.

According to the device in the embodiments of the present disclosure, the thin films of different sizes are formed through a same mask and a same thin film manufacturing device, so it is able to reduce the equipment cost. In the case of forming a plurality of layers of thin films, it is unnecessary to deliver the substrate among different devices, so it is able to reduce the possibility of the product being adversely affected by particles. In addition, it is unnecessary to design the mask for each thin film, so it is able to reduce the design cost and the management difficulty.

It should be appreciated that, in some other embodiments of the present disclosure, the thin films of different sizes on the substrate may have different thicknesses.

In addition, the thin film manufacturing device may further include a thin film formation member configured to form the thin film on the mask.

In a possible embodiment of the present disclosure, preferably, prior to the formation of the thin film, it is necessary to align the mask with the substrate. At this time, the thin film manufacturing device may further include an alignment member configured to align the mask with the substrate.

In a possible embodiment of the present disclosure, preferably, in the case that a plurality of layers of thin films is to be formed at a predetermined region of the substrate using the mask, it is merely necessary for the alignment member to align the mask with the substrate in the case of forming a first layer of thin film, and it is unnecessary to perform an alignment process in the case of forming the other layers of thin films. As a result, it is able to reduce the number of the alignment processes, thereby to reduce the alignment difficulty.

Usually, it is necessary to supply a process gas into the chamber during the formation of the thin film, and in the case that the thin films of different types are to be formed, it may be necessary to supply different process gases. Therefore, in a possible embodiment of the present disclosure, preferably, the device may further include a gas supply member configured to supply a corresponding process gas into the chamber in accordance with a type of the thin film to be formed.

In addition, preferably, in the case that the thin films of different types are to be formed continuously on the substrate using different process gases, it is necessary to discharge the process gas in the chamber for the formation of a succeeding thin film. In a possible embodiment of the present disclosure, the device may further include a gas discharge member configured to discharge the process gas in the chamber.

In a possible embodiment of the present disclosure, preferably, the substrate may be an OLED substrate, and the chamber may be used to form a thin film encapsulation layer for encapsulating the OLED substrate. In other words, the substrate carrying member is further configured to carry thereon the OLED substrate on which the thin film encapsulation layer is to be formed. The OLED substrate includes a base substrate and an OLED device arranged on the base substrate. The position adjustment member is further configured to adjust the distance between the mask and the substrate, so as to form at least two thin film encapsulation layers having different sizes on the OLED substrate.

In some embodiments of the present disclosure, the at least two thin film encapsulation layers include a first inorganic layer and an organic layer, wherein a size of the first inorganic layer is greater than a size of the organic layer. At this time, the position adjustment member is configured to adjust the distance between the mask and the substrate to be a first distance prior to the formation of the first inorganic layer, and adjust the distance between the mask and the substrate to be a second distance smaller than the first distance prior to the formation of the organic layer.

In some embodiments of the present disclosure, the at least two thin film encapsulation layers further include a second inorganic layer having a size greater than the size of the first inorganic layer. The position adjustment member is further configured to adjust the distance between the mask and the substrate to be a third distance greater than the first distance prior to the formation of the second inorganic layer.

In some embodiments of the present disclosure, an organic layer and a second organic layer may be formed using the thin film manufacturing device on the OLED substrate on which a first inorganic layer has already been formed. At this time, the position adjustment member is further configured to adjust the distance between the mask and the substrate to be a second distance prior to the formation of the organic layer, and adjust the distance between the mask and the substrate to a third distance prior to the formation of the second inorganic layer.

It should be appreciated that, during the formation of a certain layer of thin film (e.g., the first inorganic layer), the distance between the mask and the substrate is constant (e.g., the first distance). It should be appreciated that, the position adjustment member may be further configured to finely adjust the distance between the mask and the substrate in accordance with a thickness of the thin film. For example, the position adjustment member may be configured to perform the fine adjustment through detecting a thickness of the thin film or monitoring a supply time period or an amount of the process gas.

In addition, in some embodiments of the present disclosure, the position adjustment member may be further configured to adjust a size of the opening region of the mask.

In a possible embodiment of the present disclosure, the distance between the mask and the substrate may be adjusted by controlling the substrate to move upward or downward and/or controlling the mask to move upward or downward. At this time, preferably, the substrate carrying member may include a lifting table, and/or the mask fixation member may be a liftable fixation member. The position adjustment member is further configured to control the lifting table and/or the mask fixation member to move upward or downward, so as to adjust the distance between the mask and the substrate.

Based on an identical inventive concept, the present disclosure further provides in some embodiments a method for manufacturing a thin film which, as shown in FIG. 4, includes: Step 41 of placing a substrate on which the thin film is to be formed into a chamber; Step 42 of fixing a mask at one side of the substrate, the mask including a shielding region and an opening region through which a material for forming the thin film is allowed to pass; and Step 43 of adjusting a distance between the mask and the substrate, so as to form the thin films of different sizes on the substrate.

According to the method in the embodiments of the present disclosure, the thin films of different sizes are formed using a same thin film manufacturing device through adjusting the distance between the mask and the substrate, so it is able to reduce the equipment cost. In the case of forming a plurality of layers of thin films, it is unnecessary to deliver the substrate among different devices, so it is able to reduce the possibility of the product being adversely affected by particles. In addition, it is unnecessary to design the mask for each thin film, so it is able to reduce the design cost and the management difficulty.

In a possible embodiment of the present disclosure, preferably, prior to the formation of the thin film, it is necessary to align the mask with the substrate. At this time, the step of fixing the mask to one side of the substrate includes aligning the mask with the substrate.

Preferably, in the case that a plurality of thin films is to be formed at a predetermined region of the substrate using the mask, it is merely necessary for the alignment member to align the mask with the substrate in the case of forming a first layer of thin film, and it is unnecessary to perform an alignment process in the case of forming the other layers of thin films. As a result, it is able to reduce the number of the alignment processes, thereby to reduce the alignment difficulty.

In a possible embodiment of the present disclosure, preferably, the substrate is an OLED substrate, and the method is used to form a thin film encapsulation layer for encapsulating the OLED substrate.

In some embodiments of the present disclosure, the thin film encapsulation layer at least includes a first inorganic layer and an organic layer. The step of adjusting the distance between the mask and the substrate so as to form the thin films of different sizes on the substrate includes: adjusting the distance between the mask and the substrate to be a first distance, so as to form the first inorganic layer on the substrate, and adjusting the distance between the mask and the substrate to be a second distance smaller than the first distance so as to form the organic layer on the substrate.

In a possible embodiment of the present disclosure, the thin film encapsulation layer further includes a second inorganic layer, and the step of adjusting the distance between the mask and the substrate so as to form the thin films of different sizes on the substrate further includes: adjusting the distance between the mask and the substrate to be a third distance greater than the first distance so as to form the second inorganic layer on the substrate.

Preferably, the method further includes: supplying a first process gas into the chamber in the case of forming the first inorganic layer and the second inorganic layer, and supplying a second process gas different from the first process gas into the chamber in the case of forming the organic layer.

In a possible embodiment of the present disclosure, the step of adjusting the distance between the mask and the substrate includes adjusting the distance between the mask and the substrate by controlling the substrate and/or the mask to move upward or downward.

For ease of understanding, the following description will be given by taking the deposition of a thin film using the mask as an example. It should be appreciated that, the present disclosure is not limited thereto, and the device and the method in the embodiments of the present disclosure may also be applied to an evaporation process.

As shown in FIGS. 5 to 10 which are schematic views showing the method for depositing the thin film encapsulation layers onto the OLED substrate according to one embodiment of the present disclosure, the method includes the following steps.

Step 51: referring to FIG. 5, placing the OLED substrate into a chamber (e.g., a thin film deposition chamber 200). The OLED substrate includes a base substrate 101 and an OLED device 102. To be specific, the OLED substrate may be carried on and fixed by a substrate carrying member within the thin film deposition chamber 200. The substrate carrying member includes a lifting table 201.

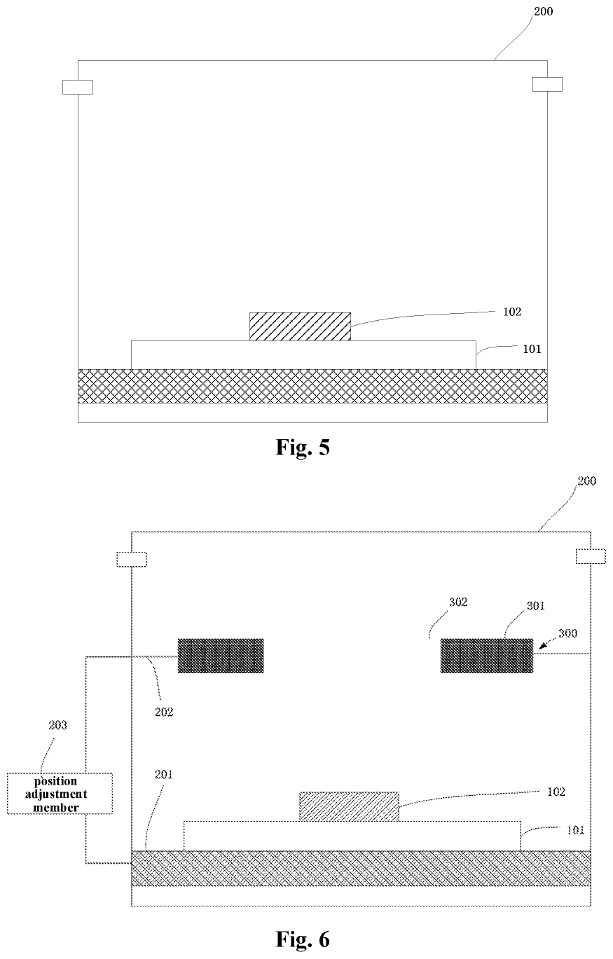

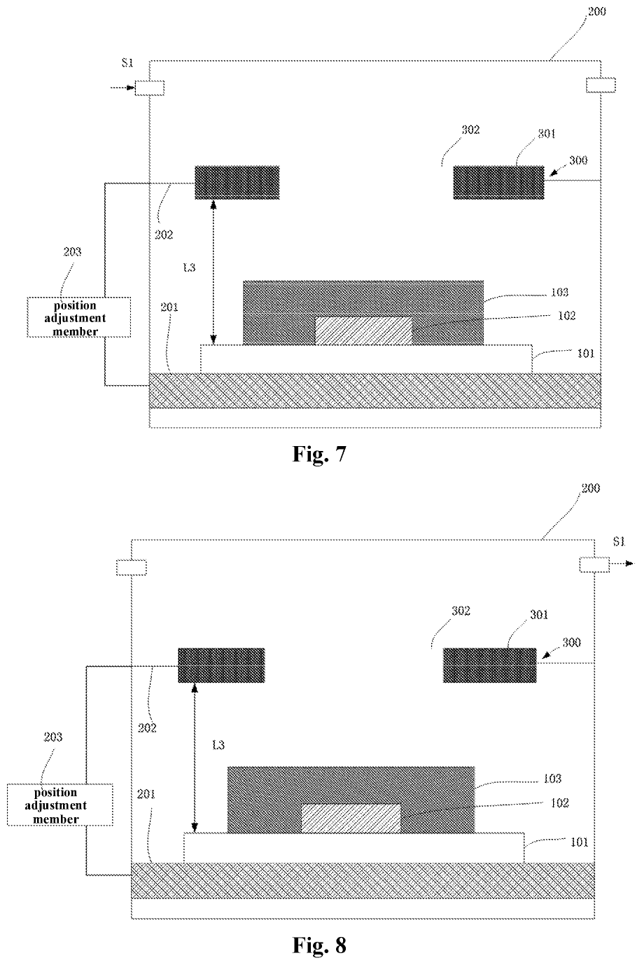

Step 52: referring to FIG. 6, fixing a mask 300 to a side of the OLED substrate, and aligning the mask 300 with the OLED substrate. The mask 300 includes a shielding region 301 and an opening region 302. To be specific, the mask 300 may be fixed through a mask fixation member 202 within the thin film deposition chamber 200. The mask fixation member 202 may be a liftable fixation member. The fixed mask 300 may be arranged parallel to the OLED substrate, and after the alignment, the opening region 302 of the mask 300 face towards a region of the OLED substrate where the thin film is to be deposited.

Step 53: referring to FIG. 7, adjusting, by a position adjustment member 203, a distance between the mask 300 and the OLED substrate to be a first distance L3, and supplying a first process gas S1 into the thin film deposition chamber 200 so as to deposit a first inorganic layer 103.

In a possible embodiment of the present disclosure, the position adjustment member 203 may control the mask fixation member 202 to move upward or downward, so as to control the mask 300 to move upward or downward, thereby to adjust the distance between the mask 300 and the OLED substrate. It should be appreciated that, in some other embodiments of the present disclosure, the position adjustment member 203 may also control the lifting table 201 to move upward or downward, so as to control the OLED substrate to move upward or downward, thereby to adjust the distance between the mask 300 and the OLED substrate.

Step 54: referring to FIG. 8, discharging the first process gas S1 within the thin film deposition chamber 200.

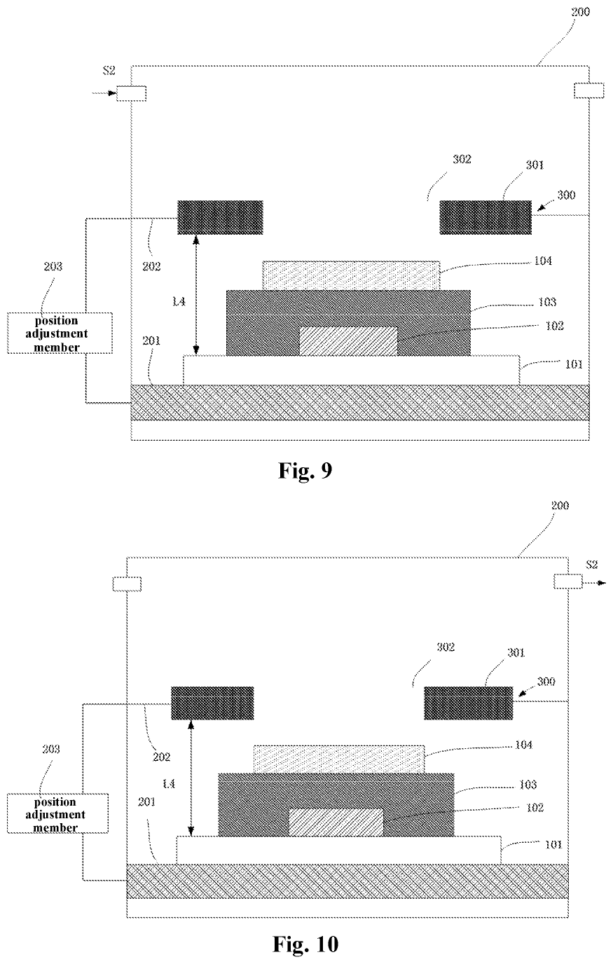

Step 55: referring to FIG. 9, adjusting, by the position adjustment member 203, the distance between the mask 300 and the OLED substrate to be a second distance L4 smaller than the first distance L3, and supplying a second process gas S2 into the thin film deposition chamber 200 so as to deposit an organic layer 104.

Step 56: referring to FIG. 10, discharging the second process gas S2 within the thin film deposition chamber 200.

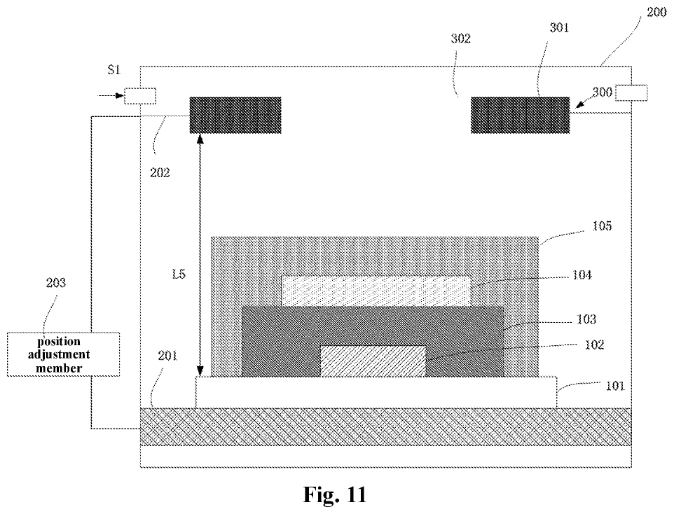

Step 57: referring to FIG. 11, adjusting, by the position adjustment member 203, the distance between the mask 300 and the OLED substrate to be a third distance L5 greater than the first distance L3, and supplying the first process gas S1 into the thin film deposition chamber 200 so as to deposit a second inorganic layer 105.

In the embodiments of the present disclosure, the distance between the mask 300 and the OLED substrate may refer to a vertical distance between the mask 300 and the base substrate 101 of the OLED substrate.

According to the method in the embodiments of the present disclosure, a plurality of the layers of the encapsulation thin films of different sizes are formed on the OLED substrate within the same thin film deposition chamber through the same mask, so it is able to reduce the equipment cost. In addition, it is unnecessary to deliver the substrate among different devices, so it is able to reduce the possibility of the product being adversely affected by particles. In addition, it is unnecessary to design the mask for each thin film, so it is able to reduce the design cost and the management difficulty.

In the embodiments of the present disclosure, the thin film deposition chamber may be a chemical vapor deposition (CVD) chamber.

To sum up, the present disclosure has the following advantages. 1) It is able to deposit the thin films of different sizes merely using one manufacture device, so as to reduce the equipment cost. 2) In the case of depositing the thin films of different sizes onto one substrate, it is unnecessary to deliver the substrate among different devices, so it is able to reduce the possibility of the product being adversely affected by particles. 3) It is necessary to align the mask with the substrate merely in the case of depositing the thin film for the first time, so it is able to reduce the alignment difficulty. 4) It is able to deposit the thin films of different sizes merely through one mask, so as to reduce the design cost and the management difficulty.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “connect” or “connected to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

The above are merely the preferred embodiments of the present disclosure. It should be appreciated that, a person skilled in the art may make further modifications and improvements without departing from the spirit of the present disclosure, and these modifications and improvements shall also fall within the scope of the present disclosure.

1. A device for manufacturing a thin film, comprising:
a chamber;
a substrate carrying member arranged within the chamber and configured to carry thereon a substrate on which the thin film is to be formed;
a mask fixation member configured to fix a mask, wherein the mask comprises a shielding region and an opening region, and a material for forming the thin film is allowed to pass through the opening region; and
a position adjustment member configured to adjust a distance between the mask and the substrate, to form the thin films of different sizes on the substrate, wherein orthogonal projections of the thin films of different sizes onto the substrate have different areas.

2. The device according to claim 1, wherein
the substrate carrying member is further configured to carry thereon an organic light-emitting diode (OLED) substrate on which a thin film encapsulation layer is to be formed, and the OLED substrate comprises a base substrate and an OLED device, wherein the OLED device is arranged on the base substrate; and
the position adjustment member is further configured to adjust a distance between the mask and the substrate, to form at least two thin film encapsulation layers of different sizes on the OLED substrate.

3. The device according to claim 2, wherein
the at least two thin film encapsulation layers comprise at least a first inorganic layer and an organic layer, and a size of the first inorganic layer is greater than a size of the organic layer; and
the position adjustment member is further configured to adjust the distance between the mask and the substrate to be a first distance prior to the formation of the first inorganic layer, and adjust the distance between the mask and the substrate to be a second distance prior to the formation of the organic layer, wherein the second distance is smaller than the first distance.

4. The device according to claim 3, wherein
the at least two thin film encapsulation layers further comprise a second inorganic layer, and a size of the second inorganic layer is greater than the size of the first inorganic layer; and
the position adjustment member is further configured to adjust the distance between the mask and the substrate to be a third distance prior to the formation of the second inorganic layer, wherein the third distance is greater than the first distance.

5. The device according to claim 2, wherein
the OLED substrate on which the thin film encapsulation layer is to be formed further comprises a first inorganic layer covering the OLED device, and the at least two thin film encapsulation layers comprise an organic layer and a second inorganic layer; and
the position adjustment member is further configured to adjust the distance between the mask and the substrate to be a second distance prior to the formation of the organic layer, and adjust the distance between the mask and the substrate to be a third distance prior to the formation of the second inorganic layer, wherein the third distance is greater than the second distance.

6. The device according to claim 1, wherein
the substrate carrying member comprises a lifting table, and the position adjustment member is further configured to control the lifting table to move upward or downward, to adjust the distance between the mask and the substrate; and/or
the mask fixation member is liftable, and the position adjustment member is further configured to control the mask fixation member to move upward or downward, to adjust the distance between the mask and the substrate.

7. The device according to claim 1, further comprising:
an alignment member configured to align the mask with the substrate, to enable the opening region of the mask to directly face a region of the substrate where the thin film is to be formed.

8. The device according to claim 1, further comprising:
a gas supply member configured to supply a corresponding process gas into the chamber in accordance with a type of the thin film to be formed.

9. The device according to claim 8, wherein
the gas supply member is further configured to set an amount of the process gas and a time period for supplying the process gas in accordance with a size and a thickness of the thin film to be formed.

10. The device according to claim 8, wherein
the gas supply member is arranged at a side of the mask distal to the substrate.

11. The device according to claim 1, wherein
the position adjustment member is further configured to, during the formation of a same thin film, adjust the distance between the mask and the substrate in accordance with a thickness of the thin film.

12. A manufacturing method, comprising:
placing a substrate onto a substrate carrying member within a chamber, wherein a thin film is to be formed on the substrate;
fixing a mask onto one side of the substrate, wherein the mask comprises a shielding region and an opening region, and a material for forming the thin film is allowed to pass through the opening region; and
adjusting a distance between the mask and the substrate to form the thin films of different sizes on the substrate, wherein orthogonal projections of the thin films of different sizes onto the substrate have different areas.

13. The method according to claim 12, wherein
placing the substrate onto the substrate carrying member within the chamber comprises: placing an organic light-emitting diode (OLED) substrate onto the substrate carrying member, wherein a thin film encapsulation layer is to be formed on the OLED substrate, and the OLED substrate comprises a base substrate and an OLED device, and the OLED device is arranged on the base substrate; and
adjusting the distance between the mask and the substrate to form the thin films of different sizes on the substrate comprises: adjusting the distance between the mask and the substrate, to form at least two thin film encapsulation layers of different sizes on the OLED substrate.

14. The method according to claim 13, wherein
the at least two thin film encapsulation layers comprise at least a first inorganic layer and an organic layer,
adjusting the distance between the mask and the substrate to form the at least two thin film encapsulation layers of different sizes on the OLED substrate comprises:
adjusting the distance between the mask and the substrate to be a first distance, and forming the first inorganic layer on the substrate; and
adjusting the distance between the mask and the substrate to be a second distance, and forming the organic layer on the substrate, wherein the second distance is smaller than the first distance, and a size of the first inorganic layer is greater than a size of the organic layer.

15. The method according to claim 14, wherein
the at least two thin film encapsulation layers further comprise a second inorganic layer;
subsequent to adjusting the distance between the mask and the substrate to be a second distance and forming the organic layer on the substrate, the method further comprises: adjusting the distance between the mask and the substrate to be a third distance, and forming the second inorganic layer on the substrate, wherein the third distance is greater than the first distance, and a size of the second inorganic layer is greater than the size of the first inorganic layer.

16. The method according to claim 15, wherein
supplying a first process gas into the chamber in the case of forming the first inorganic layer and the second inorganic layer, and supplying a second process gas into the chamber in the case of forming the organic layer, wherein the second process gas is different from the first process gas.

17. The method according to claim 12, wherein
adjusting the distance between the mask and the substrate comprises: adjusting the distance between the mask and the substrate by controlling the substrate to move upward or downward and/or controlling the mask to move upward or downward.

18. The method according to claim 12, wherein
prior to adjusting the distance between the mask and the substrate, the method further comprises: aligning the mask with the substrate, to enable the opening region of the mask to directly face a region of the substrate where the thin film is to be formed.

19. The device according to claim 2, wherein
the substrate carrying member comprises a lifting table, and the position adjustment member is further configured to control the lifting table to move upward or downward, to adjust the distance between the mask and the substrate; and/or
the mask fixation member is liftable, and the position adjustment member is further configured to control the mask fixation member to move upward or downward, to adjust the distance between the mask and the substrate.

20. The device according to claim 2, further comprising:
an alignment member configured to align the mask with the substrate, to enable the opening region of the mask to directly face a region of the substrate where the thin film is to be formed.
